(19) United States
(12) Patent Application Publication
(10) Pub. No.: US 2006/0171128 A1
(43) Pub. Date: Aug. 3, 2006

(54) Plasma display device

(76) Inventor: Dong-Hyok Shin, Suwon-si (KR)

Correspondence Address: CHRISTIE, PARKER & HALE, LLP, PO BOX 7068, PASADENA, CA, 91109-7068, US

(21) Appl. No.: 11/323,373

(22) Filed: Dec. 29, 2005

(30) Foreign Application Priority Data
Jan. 31, 2005 (KR) 10-2005-0008583

(51) Int. Cl. H05K 7/14

(52) U.S. Cl. 361/752; 361/759; 361/796; 361/801

(57) ABSTRACT

A display device includes a display panel, a chassis base for mounting the display panel, a printed circuit board assembly mounted on the chassis base and electrically connected to the display panel, and at least one bracket member disposed between the chassis base and the printed circuit board assembly such that the printed circuit board assembly is mounted thereto using a fastening member. The display panel may be a plasma display panel.

### CROSS-REFERENCE TO RELATED APPLICATION

This application claims priority to and the benefit of Korean Patent Application No. 10-2005-0008583 filed in the Korean Intellectual Property Office on Jan. 31, 2005, the entire content of which is incorporated herein by reference.

### BACKGROUND OF THE INVENTION

1. Field of the Invention

The present invention relates to a display device. More particularly, the present invention relates to a plasma display device having an improved structural configuration.

2. Description of the Related Art

Recently, a number of various display devices have been developed. Among those devices is a plasma display device. Generally, a plasma display device is an apparatus that displays an image on a plasma display panel (PDP) using plasma generated by a gas discharge.

Typically, a plasma display device includes the PDP, a chassis base supporting the PDP, and a plurality of printed circuit board assemblies (PBAs) mounted to the chassis base on a side opposite to the PDP. The PBA is connected to display electrodes or address electrodes, e.g., through a flexible printed circuit (FPC) and a connector.

Since the PDP includes two glass substrates attached to each other at their surfaces with discharge spaces formed therebetween, such a PDP displays weak mechanical strength against an impact. Further, the PDP produces substantial heat during operation, and accordingly, a thermal conduction sheet is provided on one of its lateral surfaces. The thermal conduction sheet conducts heat produced by the PDP to spread it in planar directions.

The chassis base is formed of a metallic material having sufficient mechanical strength to support the PDP, and is attached to the PDP by double-sided adhesive tape. In addition to reinforcing the strength of the PDP, the chassis base supports the PBAs, dissipates the heat of the PDP, and prevents electromagnetic interference (EMI).

In addition, the chassis base is provided with a plurality of boss members for mounting the PBAs and/or reducing the EMI by grounding the PBAs. Accordingly, a PBA is fixedly mounted on the chassis base through the boss members by fastening members (e.g., screws).

In addition, a PBA is provided with a grounding portion around a fastening hole so as to reduce EMI by grounding a circuit of the PBA to the chassis base. The grounding portion is typically formed as a circular penetration hole which may be used for fastening the PBA to the chassis base through the boss members.

The chassis base is usually provided with a plurality of PBAs, and therefore, it is also provided with a sufficient number of boss members for mounting such PBAs.

When the mounting positions of the PBAs are changed, a mold for the chassis base also must be changed to accommodate the new PBA position.

The above information disclosed in this Background section is only for enhancement of understanding of the background of the invention, and therefore, it may contain information that does not form the prior art that is already known in this country to a person of ordinary skill in the art.

### SUMMARY OF THE INVENTION

The present invention provides a display device eliminating the need to change a mold for a chassis base in accordance with changing the mounting position of a printed circuit board assembly.

An exemplary display device according to an embodiment of the present invention includes a display panel, a chassis base for mounting the display panel, a PBA mounted on the chassis base and electrically connected to the display panel, and at least one bracket member disposed between the chassis base and the PBA such that the PBA is mounted to the bracket member using a fastening member.

The chassis base and the bracket member may be integrally formed. The bracket member may include a plate and a plurality of fin members protruding from the plate. The plate and the fin members may be formed of a metallic material such as aluminum or an aluminum alloy.

### BRIEF DESCRIPTION OF THE DRAWINGS

FIG. 1 is an exploded perspective view showing a plasma display device according to an exemplary embodiment of the present invention.

FIG. 2 is a cross-sectional view along a line A-A of FIG. 1.

FIG. 3 is a cross-sectional view along a line A-A of FIG. 1 according to an alternate embodiment of the present invention.

FIG. 4 is an exploded perspective view showing a plasma display device according to another exemplary embodiment of the present invention.

FIG. 5 is an exploded perspective view showing a plasma display device according to yet another exemplary embodiment of the present invention.

### DETAILED DESCRIPTION OF THE EMBODIMENTS

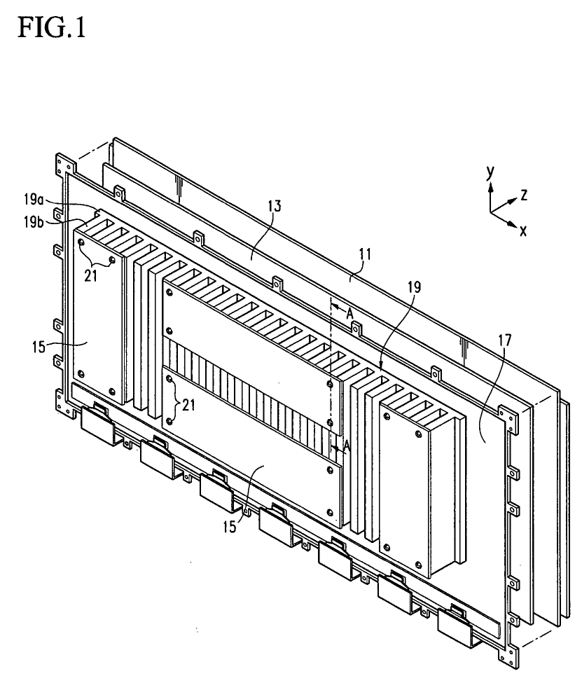

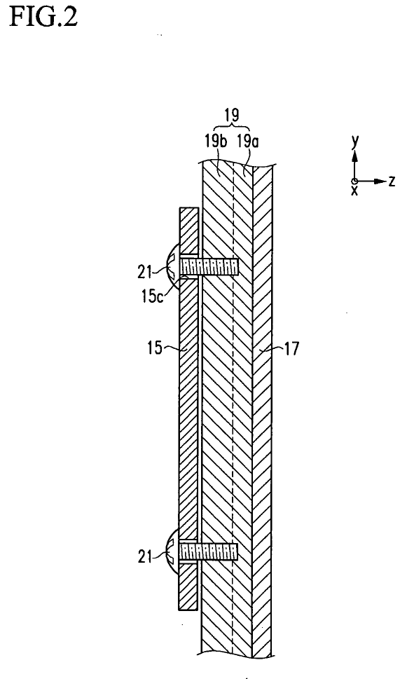

Referring to FIGS. 1 and 2, a plasma display device according to an exemplary embodiment of the present invention includes a PDP 11, a heat dissipation sheet 13, printed circuit board assemblies (PBAs) 15, and a chassis base 17. The PDP 11 displays an image using a gas discharge. The heat dissipation sheet 13 dissipates heat generated by the PDP 11 in planar directions (refer to x-y direction in the drawings). The printed circuit board assemblies (PBAs) 15 are electrically connected to the PDP 11 in order to drive the PDP. The chassis base 17 is mounted to the PDP 11 at a first chassis base surface

The heat dissipation sheet 13 may be made of a heat dissipation material showing sufficient thermal conductivity such as acryl, graphite, metal, or carbon nanotubes.

The PBA 15 may be mounted to a surface of the chassis base 17 opposite to the surface mounting the PDP 11 through the bracket member 19 using fastening members, such as a plurality of screws 21. The screw 21 penetrates the fastening hole 15c of the PBA 15 and is engaged with a bracket member 19.

An image processing/controlling board among the PBAs 15 exteriorly receives a video signal, generates control signals for driving address electrodes and display electrodes (not shown), and applies the control signals to an address buffer board, a scan driving board, and a sustain driving board. A power supply board among the PBAs 15 supplies electric power required for driving the plasma display device. For driving the PDP 11, the address buffer board, the scan driving board, and the sustain driving board are connected with the address electrodes, scan electrodes, and sustain electrodes, respectively, of the PDP 11 through FPCs, and they are connected with the power supply board through flexible flat cables (FFCs) (not shown).

The PBAs 15 are electrically connected to the PDP 11, and are provided with circuits for designed functions of the PBAs and grounding portions. The grounding portion is provided with a fastening hole 15c for mounting the PBA 15 by screw 21.

As shown in FIGS. 1 and 2, the bracket member 19 includes a plate 19a and fin members 19b protruding from the plate 19a. The plate 19a and the fin members 19b may be formed from a metallic material, and more specifically, they may be formed from aluminum (Al) or an aluminum alloy. Such a bracket member 19 may act as a heat sink having the plate 19a and heat dissipating fins of the fin member 19b.

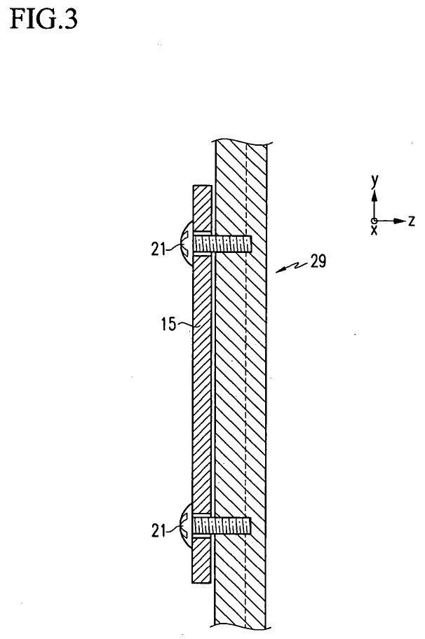

According to another exemplary embodiment, a bracket member may be formed integral with the chassis base 17 so as to form a bracket member 29 as shown in FIG. 3.

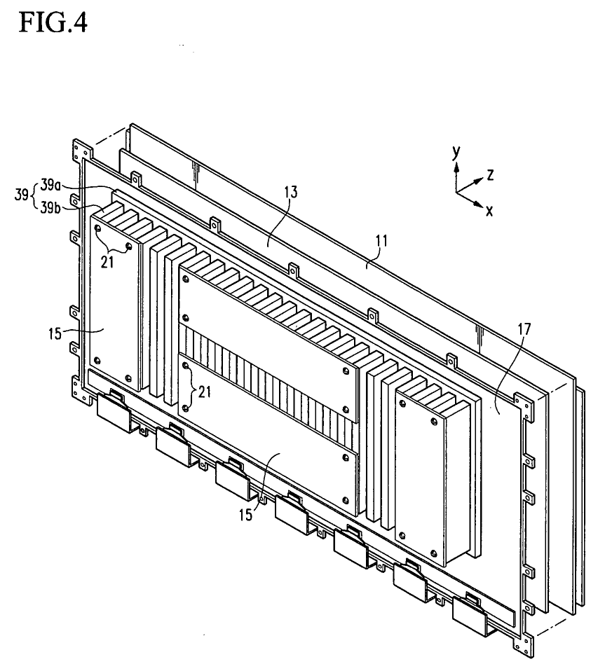

According to yet another exemplary embodiment of the present invention shown in FIG. 4, a bracket member 39 is formed by combining a plate 39a and fin members 39b that are separately provided. The plate 39a and the fin members 39b may be combined with each other by various ways, for mere example, by welding, by an adhesive such as a glue and a double-sided adhesive tape. The plate 39a may be formed from metallic material such as aluminum or an aluminum alloy, and the fin members 39b may be formed from a non-metallic material. Alternatively, both the plate 39a and the fin members 39b may be formed from a non-metallic material, for example, plastic.

The PBA 15 is fixedly mounted to the fin members 39b of the bracket member 39. The plate 39a and the fin members 39b may be integrally formed to form the bracket member 39, as described above with respect to FIGS. 1 and 2.

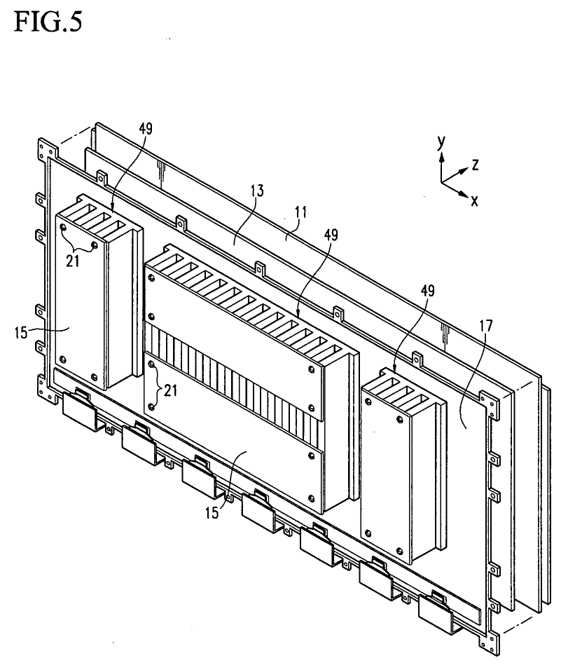

According to another exemplary embodiment of the present invention shown in FIG. 5, individual bracket members 49 are provided in accordance with the number of PBAs 15 and their arrangement. That is, the number of bracket members 49 may be equal to the number of PBAs 15, or, as shown in FIG. 5, may have multiple PBAs 15 mounted on an individual bracket member 19.

Hereinafter, an operation of a plasma display device according to exemplary embodiments of the present invention will be described in detail.

According to an exemplary plasma display device of the present invention as shown in FIG. 1 and FIG. 2, a bracket member 19 having the plate 19a and fin members 19b is combined with the chassis base 17. The bracket member 19 may be combined with the chassis base 17 in various ways, for example, by welding, by a double-sided adhesive tape, by a fastener such as bolts, etc, either interposing a heat conducting medium therebetween or not. The PBAs 15 are fixedly mounted to fin members 19b of the bracket member 19 using screws 21. In this case, the bracket member 19 is in the form of a heat sink in which the plate 19a and the fin members 19b are integrally formed. Therefore, the bracket member 19 may be mounted with the PBAs 15, and it may also dissipate heat generated by the PDP 11 and/or the PBAs 15.

In addition, the bracket member 19 may be integrally formed with the chassis base 17, as described in connection with reference to FIG. 3. That is, the fin members 19a may be combined with or formed on the chassis base 17 so as to be mounted with the PBAs 15. Therefore, a unified bracket member 29 (FIG. 3) may provide the same effect as the separately provided bracket member 19 as shown in FIG. 1 and FIG. 2.

In addition, the plate 39a and the fin members 39b may be separately fabricated and then unified to form the bracket member 39, as described with reference to FIG. 4. According to such a configuration, a short circuit may be prevented by forming the plate 39a with a metallic material such as aluminum and the fin members 39b with a non-metallic material such as plastic.

In addition, a plurality of bracket members 49 may be provided in accordance with the number of PBAs 15 as needed, as described in connection with reference to FIG. 5.

In addition, fin members may be formed having a length adapted to prevent a short circuit as the PBA 15 is mounted to the fin members 19a, 29a, 39a of the bracket members 19, 29, 39, 49. In order to prevent interference from foreign particles, the fastening member (i.e., the screw 21) may be formed of a non-metallic material, for example, plastic.

According to embodiments of the present invention, a bracket member (e.g., a heat sink) having fin members is formed on the chassis base and the PBA is mounted to the fin members. Therefore, the mold for the chassis base does not necessarily have to be changed when the mounting position of a PBA is changed. This allows frequent design change of the mold for the chassis base to be prevented, and thereby reducing the manufacturing cost of a plasma display device.

In addition, a fin member acting as a heat sink is formed on the chassis base, and therefore, heat generated by a PDP and PBAs may be effectively dissipated. In addition, the fin members where the PBA is mounted may be formed of a non-metallic material, thereby preventing a short circuit.

While this invention has been described in connection with exemplary embodiments, it is to be understood that the invention is not limited to the disclosed embodiments, but is intended to cover various modifications and equivalent arrangements included within the spirit and scope of the appended claims.

What is claimed is:

1. A display device comprising:
a display panel;
a chassis base on which the display panel is mounted;
at least one printed circuit board assembly mountable to the chassis base and electrically connected to the display panel; and
at least one bracket member disposed between the chassis base and the at least one printed circuit board assembly,
wherein the at least one printed circuit board assembly is mounted to at least one bracket member using a fastening member.

2. The display device of claim 1, wherein the chassis base and the at least one bracket member are integrally formed.

3. The display device of claim 1, wherein the at least one bracket member includes a plate and a plurality of fin members protruding from the plate.

4. The plasma display device of claim 3, wherein the plate and the plurality of fin members are formed from a metallic material.

5. The display device of claim 4, wherein the metallic material is aluminum.

6. The display device of claim 3, wherein the plate and the plurality of fin members are integrally formed.

7. The plasma display device of claim 3, wherein the plate is formed of a metallic material, and the plurality of fin members are formed of a non-metallic material.

8. The display device of claim 3, wherein the plate and the plurality of fin members are formed from a non-metallic material.

9. The display device of claim 8, wherein the non-metallic material is plastic.

10. The display device of claim 3, wherein the at least one printed circuit board assembly is fixedly mounted to the plurality of fin members.

11. The display device of claim 3, wherein each of a plurality of bracket members have one or more printed circuit board assemblies mounted on respective bracket members.

12. The display device of claim 1, wherein the fastening member is formed from a non-metallic material.

13. The display device of claim 12, wherein the fastening member includes a plastic screw.

14. The display device of claim 1, wherein the display panel is a plasma display panel.

15. A bracket member for a display device, the display device including a display panel, a chassis base on which the display panel is mounted, and at least one printed circuit board assembly for mounting on the chassis base and being electrically connected to the display panel, the bracket member comprising:
a plate; and
a plurality of fin members;
wherein the bracket member is adapted to be mounted between the at least one printed circuit board and the chassis base.

16. The bracket member of claim 15, wherein the display device is a plasma display device.
